(19) United States
(12) Patent Application Publication
(10) Pub. No.: US 2023/0390883 A1
(43) Pub. Date: Dec. 7, 2023

(54) ACOUSTIC MONITORING OF CMP RETAINING RING

(71) Applicant: Applied Materials, Inc., Santa Clara, CA (US)

(72) Inventors: Haoquan Fang, Sunnyvale, CA (US); Thomas H. Osterheld, Mountain View, CA (US); Benjamin Cherian, San Jose, CA (US); Jun Qian, Sunnyvale, CA (US); Kun Xu, Sunol, CA (US); Sohrab Pourmand, San Jose, CA (US); Boguslaw A. Swedek, Morgan Hill, CA (US); Jeonghoon Oh, Saratoga, CA (US); Dominic J. Benvegnu, La Honda, CA (US); Brian J. Brown, Palo Alto, CA (US)

(21) Appl. No.: 17/961,516

(22) Filed: Oct. 6, 2022

Related U.S. Application Data
(60) Provisional application No. 63/349,000, filed on Jun. 3, 2022.

(51) Int. Cl. B24B 37/005; B24B 37/32; G01N 29/44; G01N 29/46

(52) U.S. Cl. CPC B24B 37/005; B24B 37/32; G01N 29/4436; G01N 29/4427; G01N 29/46

(57) ABSTRACT

A chemical mechanical polishing apparatus includes a platen supporting a polishing pad, a carrier head to hold a surface of a substrate against the polishing pad, an acoustic sensor supported on the platen, and a motor to generate relative motion between the platen and the carrier head so as to polish the substrate. The carrier head includes a retaining ring for holding the substrate, and the acoustic sensor travels in a path below the carrier head and the retaining ring. A controller is configured to analyze a signal from the acoustic sensor and determine a characteristic of the retaining ring based on the signal.

### CROSS-REFERENCE TO RELATED APPLICATIONS

This application claims the benefit of priority to U.S. Application No. 63/349,000, filed on Jun. 3, 2022, the contents of which are hereby incorporated by reference.

### TECHNICAL FIELD

This disclosure relates to in-situ monitoring of chemical mechanical polishing, and in particular to acoustic monitoring.

### BACKGROUND

An integrated circuit is typically formed on a substrate by the sequential deposition of conductive, semiconductive, or insulative layers on a silicon wafer. One fabrication step involves depositing a filler layer over a non-planar surface and planarizing the filler layer. For certain applications, e.g., to fill trenches or holes in an insulative layer with a conductive filler material, the filler layer is planarized until the top surface of a patterned layer is exposed. For other applications, such as oxide polishing, the filler layer is planarized, e.g., by polishing for a predetermined time period, to leave a portion of the filler layer over the nonplanar surface. In addition, planarization of the substrate surface is usually required for photolithography.

Chemical mechanical polishing (CMP) is one accepted method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. A carrier head typically includes a retaining ring to surround the substrate and hold the substrate below the carrier head. A lower surface of the retaining ring can be pressed against the polishing pad and can wear away as polishing progresses. Thus the retaining ring may need to be replaced periodically.

In some systems, the substrate is monitored in-situ during polishing. Acoustic monitoring of the substrate during polishing has been proposed.

### SUMMARY

In one aspect, a chemical mechanical polishing apparatus includes a platen to support a polishing pad, a carrier head to hold a surface of a substrate against the polishing pad, an acoustic sensor supported on the platen, and a motor to generate relative motion between the platen and the carrier head so as to polish the substrate. The carrier head includes a retaining ring for holding the substrate, and the acoustic sensor travels in a path below the carrier head and the retaining ring. A controller is configured to analyze a signal from the acoustic sensor and determine a characteristic of the retaining ring based on the signal.

In another aspect, a chemical mechanical polishing apparatus includes a platen to support a polishing pad, a carrier head to hold a surface of a substrate against the polishing pad, an acoustic sensor supported on the platen, and a motor to generate relative motion between the platen and the carrier head so as to polish the substrate. The carrier head includes a retaining ring for holding the substrate, and the acoustic sensor travels in a path below the carrier head and retaining ring. The controller is configured to select portions of a signal from the acoustic sensor corresponding to the acoustic sensor being below the retaining ring and to generate an alert or to modify a polishing parameter based on the selected portions of the signal from the acoustic sensor.

One or more of the following possible advantages may be realized. The retaining ring can be monitored in a real-time and in-situ manner. Whether the retaining ring is “broken in” can be determined with in-situ monitoring, thus reducing time needed for qualification of the polishing system. The wear status of a retaining ring can be monitored. A signal from the acoustic monitoring system can depend on the flatness or taper angle of the bottom surface of the retaining ring, and this signal can be used to as basis for adjustment of other polishing parameters to improve wafer-to-wafer (WTW) and within-wafer (WIW) polishing uniformity.

The details of one or more embodiments are set forth in the accompanying drawings and the description below. Other aspects, features and advantages will be apparent from the description and drawings, and from the claims.

### DESCRIPTION OF DRAWINGS

FIG. 1 illustrates a schematic cross-sectional view of an example of a polishing system.

FIG. 2 illustrates a top view of a polishing system.

FIG. 3 illustrates a schematic cross-sectional view of an acoustic monitoring sensor below a retaining ring of a carrier head.

In the figures, like references indicate like elements.

### DETAILED DESCRIPTION

During polishing, the polishing pad wears away the bottom surface of the retaining ring. Typically, wearing does not occur at an even rate radially across the retaining ring, so that the bottom surface takes on a non-flat geometry. However, the wearing of the retaining ring eventually comes to an equilibrium, such that the bottom surface of the retaining ring retains the substantially same geometry as the ring wears until the process or polishing conditions change. Due to the ongoing change in retaining ring geometry, the polishing rate profile will drift until the retaining ring reaches equilibrium.

To reduce substrate to substrate or across substrate polishing variation, the retaining ring can be “broken in” before being used in the polishing process. One way of breaking in a retaining ring is to simulate substrate polishing, e.g., by pressing the retaining ring against a moving polishing pad so that the ring wears until it reaches the equilibrium geometry. However, a disadvantage of “break-in” is that it is time consuming and requires use of the polishing apparatus. As a result, the break-in process is down-time of the polishing apparatus during which no polishing can be performed, increasing cost of ownership.

By acoustically monitoring the retaining ring, the time at which the retaining ring is broken in can be determined in real-time and in-situ. Thus, time required for break-in can be reduced.

As another issue, the impact of the substrate on the inner surface of the retaining ring can generate grooving on the inner surface. This grooving can, in turn, influence pressure applied to the substrate edge and thus affect polishing uniformity.

By acoustically monitoring the retaining ring, the formation of grooving on the inner surface of the retaining ring can be detected. This permits the retaining ring to be replaced promptly, thus reducing the likelihood of polishing non-uniformity.

More generally, acoustic monitoring of the retaining ring can be used to improve the polishing process. For example, signals from an acoustic monitoring system can be indicative of the geometry and/or smoothness of the lower surface of the retaining ring, which can impact the polishing profile of the substrate, particularly near the substrate edge. Thus, these signals can be used as inputs for control of various polishing parameters, e.g., pressure applied in various regions of the substrate, to improve polishing performance.

Any of these issues could be used addressed independent of the other issues, or a system could address multiple issues.

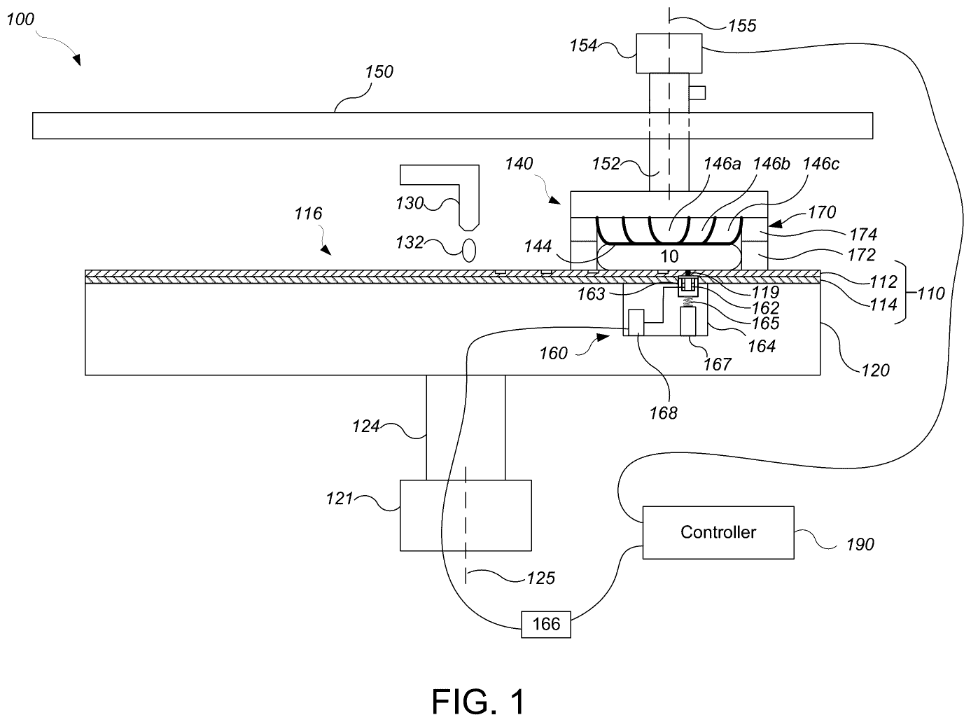

FIG. 1 illustrates an example of a polishing apparatus 100. The polishing apparatus 100 includes a rotatable disk-shaped platen 120 on which a polishing pad 110 is situated. The polishing pad 110 can be a two-layer polishing pad with an outer polishing layer 112 and a softer backing layer 114. The platen is operable to rotate about an axis 125. For example, a motor 121, e.g., a DC induction motor, can turn a drive shaft 124 to rotate the platen 120.

The polishing apparatus 100 can include a port 130 to dispense polishing liquid 132, such as abrasive slurry, onto the polishing pad 110 to the pad. The polishing apparatus can also include a polishing pad conditioner to abrade the polishing pad 110 to maintain the polishing pad 110 in a consistent abrasive state.

The polishing apparatus 100 includes a carrier head 140. The carrier head 140 is operable to hold a substrate 10 against the polishing pad 110. The carrier head 140 includes a retaining ring 170 to retain the substrate 10 below a flexible membrane 144. The retaining ring 170 can include a lower portion 172 formed of a wearable plastic that is compatible with the polishing process, e.g., PPS, and upper portion 174 formed of a more rigid material, e.g., a metal. Alternatively the entire retaining ring can be formed of a plastic. The retaining ring 170 is typically secured to the carrier head 140 with screws so that the retaining ring 170 can be removed and replaced.

The carrier head 140 also includes one or more independently controllable pressurizable chambers defined by the membrane, e.g., three chambers 146a-146c, which can apply independently controllable pressurizes to associated zones on the flexible membrane 144 and thus on the substrate 10 (see FIG. 1). Although only three chambers are illustrated in FIG. 1 for ease of illustration, there could be one or two chambers, or four or more chambers, e.g., five chambers.

The carrier head 140 is suspended from a support structure 150, e.g., a carousel or track, and is connected by a drive shaft 152 to a carrier head rotation motor 154, e.g., a DC induction motor, so that the carrier head can rotate about an axis 155. Optionally each carrier head 140 can oscillate laterally, e.g., on sliders on the carousel 150, or by rotational oscillation of the carousel itself, or by sliding along the track. In typical operation, the platen is rotated about its central axis 125, and each carrier head is rotated about its central axis 155 and translated laterally across the top surface of the polishing pad.

A controller 190, such as a programmable computer, is connected to the motors 121, 154 to control the rotation rate of the platen 120 and carrier head 140. For example, each motor can include an encoder that measures the rotation rate of the associated drive shaft.

The polishing apparatus 100 includes at least one in-situ acoustic monitoring system 160. The in-situ acoustic monitoring system 160 includes one or more acoustic signal sensors 162. Each acoustic signal sensor can be installed at one or more locations on the platen 120. In particular, the in-situ acoustic monitoring system can be configured to detect acoustic signals from the retaining ring 170.

A position sensor, e.g., an optical interrupter connected to the rim of the platen or a rotary encoder, can be used to sense the angular position of the platen 120. This permits only portions of the signal measured when the sensor 162 is in proximity to the retaining ring 170, e.g., when the sensor 162 is below the retaining ring, to be used as indicative of the retaining ring condition in subsequent signal processing.

In the implementation shown in FIGS. 1 and 3, the acoustic monitoring system 160 includes an acoustic sensor 162 positioned supported by the platen 120 to receive acoustic signals through the polishing pad 110 from the substrate 10. The acoustic sensor 162 can be partially or entirely in a recess 164 in the top surface of the platen 120. In some implementations, a top surface of the acoustic sensor 162 is coplanar with the top surface of the platen 120.

In some implementations, the portion of the polishing pad directly above the acoustic sensor 162 can include an acoustic window 119, e.g., a region having lower acoustic impedance than the surrounding polishing material. The acoustic window 119 can extend through the polishing layer 112, or the backing layer 114, or both. However, if the acoustic transmission of the polishing pad is sufficiently high, the acoustic window 119 may not be necessary.

The acoustic sensor 162 is a contact acoustic sensor having a surface connected to (e.g., in direct contact with, or having just an adhesive layer for attachment to, or having just an acoustic gel for transmission of the acoustic signal from) a portion of the polishing pad, e.g., the polishing layer 112, or the backing layer 114, or the acoustic window 119. For example, the acoustic sensor 162 can be an electromagnetic acoustic transducer or piezoelectric acoustic transducer. A piezoelectric sensor can include a rigid contact plate, e.g., of stainless steel or the like, which is placed into contact with the body to be monitored, and a piezoelectric assembly, e.g., a piezoelectric layer sandwiched between two electrodes, on the backside of the contact plate.

In some implementations, the acoustic sensor 162 is positioned within a recess 169 in a housing 163. An optional spring 165 can be arranged between the housing 163 and a support 167 provides pressure against the housing 163. The pressure on the housing 163 presses the acoustic sensor 162 into contact with a portion of the polishing pad 110. Alternatively, the spring 165 can press directly against the acoustic sensor 162, e.g., if a housing is not used. In some implementations, the spring 165 is a long travel spring 165 supplying similar pressure as the strong spring 165 over larger compression ranges.

The acoustic sensor 162 can be connected by circuitry 168 to a power supply and/or other signal processing electronics 166 through a rotary coupling, e.g., a mercury slip ring.

In some implementations, the in-situ acoustic monitoring system 160 is a passive acoustic monitoring system. In this case, signals are monitored by the acoustic sensor 162 without generating signals from an acoustic signal generator (or the acoustic signal generator can be omitted entirely from the system). The passive acoustic signals monitored by the acoustic sensor 162 can be in 50 kHz to 1 MHz range, e.g., 200 to 400 kHz, or 200 Khz to 1 MHz. For example, for monitoring of polishing of inter-layer dielectric (ILD) in a shallow trench isolation (STI), a frequency range of 225 kHz to 350 kHz can be monitored.

The signal from the sensor 162 can be amplified by a built-in internal amplifier, or by an external amplifier. In some implementations, the amplification gain is between 40 and 60 dB (e.g., 50 dB). The signal from the acoustic sensor 162 can then be further amplified and filtered if necessary, and digitized through an A/D port to a high speed data acquisition board, e.g., in the electronics 166. Data from the acoustic sensor 162 can be recorded at a similar range as that of the generator 163 or at a different, e.g., higher, range, e.g., from 1 to 10 Mhz, e.g., 1-3 MHz or 6-8 Mz. In implementations in which the acoustic sensor 162 is a passive acoustic sensor, a frequency range from 100 kHz to 2 MHz can be monitored, such as 500 kHz to 1 MHz (e.g., 750 kHz).

If positioned in the platen 120, the acoustic sensor 162, can be located at the center of the platen 120, e.g., at the axis of rotation 125, at the edge of the platen 120, or at a midpoint (e.g., 5 inches from the axis of rotation for a 20 inch diameter platen).

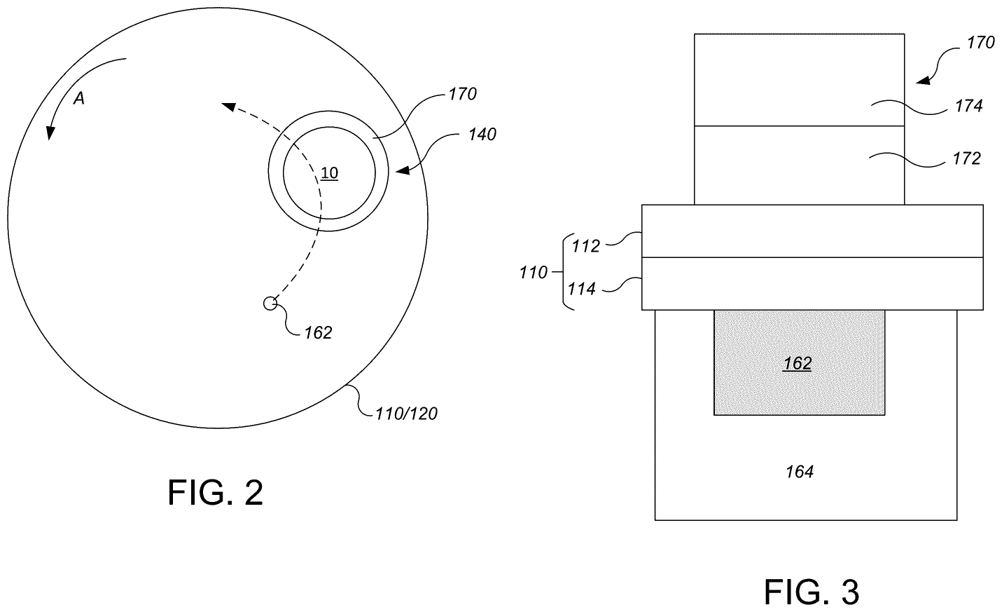

Referring to FIG. 2, due to motion of the platen 120 (shown by arrow A), the sensor 162 sweeps in a path (shown by phantom arrow B) that travels below the retaining ring 170 and the substrate 10. The acoustic monitoring system 160, e.g., the controller 190, can be configured to sample signals from the sensor 162 when the sensor is passing below the retaining ring 170. For example, the controller 190 can determine the angular position of the sensor 162 based on input from a motor encoder or the platen position sensor, and compare this to a position of the carrier head 140 and retaining ring 170, e.g., based on sweep information. Determination of the position of a sensor relative to the substrate is discussed in U.S. Pat. No. 6,159,073 and in U.S. Pat. No. 6,296,548. This permits the portions of the signal received when the sensor 162 is below the retaining ring 170 to be identified and selected. Portions of the signal corresponding to the sensor being in other positions, e.g., below the substrate 10 or not below the carrier head 140 at all, can be used for other monitoring purposes such as detection of defects on the substrate 10, but need not be used in the retaining ring monitoring discussed below.

Returning to FIGS. 1 and 3, acoustic signals generated by the interface between the retaining ring 174 and the polishing layer 112 of the pad 110 travel through the polishing pad 110 and are received by the acoustic sensor 162. The acoustic sensor 162 transmits the received to signal processing electronics 166 which perform functions on the received acoustic signal. The electronics 166 can include, for example, a filter, an amplifier, a spectrum analyzer, a data acquisition system (DAQ), or other components for processing the received acoustic signal. In general, the electronics 166 can include a general purpose programmable computer, dedicated circuitry, or a combination thereof. In some implementations, the electronics 166 is within, e.g., implemented by, the controller 190.

The signal from the acoustic sensor 162, e.g., after amplification, preliminary filtering and digitization, can be subject to data processing, e.g., in the controller 190, for either detection of various stages of retaining ring, e.g., that the retaining ring is broken in or that grooving has been formed on the inner surface of the retaining ring, or for feedback or feedforward control of polishing parameters. The controller 190 can generate an alert indicating the type of event, e.g., the alert can indicate which of retaining ring break-in or the formation of grooving (or other possible events, such as an unclassified event) has occurred.

In some implementations, the controller 190 is configured to monitor a change in acoustic signal strength. For example, for an active acoustic monitoring system (in which the sensor 162 emits acoustic energy), the received signal strength is compared to the emitted signal strength to generate a normalized signal, and the normalized can be monitored over time to detect changes. As another example, for an passive acoustic monitoring system, the received signal strength is compared to a measured initial signal strength, e.g., obtained at when the retaining ring is newly installed on the carrier head, to generate a normalized signal, and the normalized can be monitored over time to detect changes. Such changes can indicate that the retaining ring has been broken-in.

In some implementations, a frequency analysis of the signal is performed. For example, frequency domain analysis can be used to determine changes in the relative power of spectral frequencies, and to determine when a film transition has occurred at a particular radius. Information about time of transition by radius can be used to trigger endpoint. As another example, a Fast Fourier Transform (FFT) can be performed on the signal to generate a frequency spectrum. A particular frequency band can be monitored, and if the intensity in the frequency band crosses a threshold value, this can indicate a change in the retaining ring, e.g., that the retaining ring has been broken-in or that grooving is being formed on the inner surface of the retaining ring. Alternatively, if a location (e.g., wavelength) or bandwidth of a local maxima or minima in a selected frequency range crosses a threshold value, this can indicate a change in the retaining ring.

In some implementations, a spectrum (e.g., power, wavelength or frequency spectrum) of signal can be compared to a reference spectrum. If the difference, e.g., a summed square of differences over the power, wavelength or frequency range, exceeds or falls below a threshold, this can indicate a change in the retaining ring, e.g., that the retaining ring has been broken-in or that grooving is being formed on the inner surface of the retaining ring.

Determination of the appropriate characteristic of the signal to monitor and the appropriate criterion for triggering an indication of a change in the retaining ring can be determined empirically. For example, polishing can be performed with a worn retaining ring that is known to be in equilibrium, and the spectrum of the signal from this retaining ring can be used as a reference spectrum. As another example, polishing can be performed with both a fresh retaining ring and a worn retaining ring that is known to be in equilibrium. The spectra of the signals can be compared to empirically determine a power, wavelength or frequency band for monitoring, and whether the worn retaining ring has higher or lower signal strength within that band. Criteria for the signal to generate an alert indicating that the retaining ring is broken in can be derived, and the controller 190 can be configured to test whether the signal meets the criteria.

As another example, polishing can be performed with a retaining ring that is known to have grooving on an inner surface, and the spectrum of the signal from this retaining ring can be used as a reference spectrum. As another example, polishing can be performed with both a fresh retaining ring and a retaining ring that is known to have grooving on the inner surface. The spectra of the signals can be compared to empirically determine a power, wavelength or frequency band for monitoring, and whether the retaining ring with grooving has higher or lower signal strength within that band. Criteria for the signal to generate an alert indicating that the retaining ring has grooving can be derived, and the controller 190 can be configured to test whether the signal meets the criteria.

In operation, an acoustic signal is collected from the in-situ acoustic monitoring system 160. The signal is monitored to detect a change in the retaining ring. Detection of the change can trigger an alert to an operator, or can automatically halt the polishing operation. In the case of a retaining ring that is broken in, the retaining ring may then be used. The retaining ring might be removed from the polishing system for use in another polishing system, or the polishing system might be converted from polishing of dummy substrates to polishing of device substrates for actual integrated circuit production. In the case of a retaining ring that has grooving on the interior surface, the operator can replace the retaining ring.

In some implementations, the controller 190 controls one or more components of the apparatus 100, such motors that control rotation rates of the carrier head 140 or platen 120 or pressure controllers that control pressures within the chambers 146a-c based on the received acoustic signals.

The acoustic monitoring signal collected from the retaining ring can be used can be used in feed forward to control processing of the substrate in a subsequent processing operation, e.g., polishing at a subsequent station, or in feed back to control processing of a subsequent substrate at the same polishing station. For example, signal strength in one or more power, wavelength or frequency bands can be correlated with the polishing rate in one or more regions, e.g., radial zones, of the substrate. A control algorithm can accept the acoustic monitoring signal and determine an adjustment to one or more pressures applied by the polishing head in order to improve polishing uniformity.

In some implementations, portions of the signal obtained from the sensor below the substrate can be used. For example, grooving on an interior surface of the retaining ring can generate vibrations in the substrate that may be sensed by the acoustic sensor. Again, polishing can be performed with a retaining ring that is known to have grooving on an inner surface, and the spectrum of the signal (including portions of the signal corresponding to the sensor being below the substrate) can be used, either as a reference spectrum or to determine criteria to generate an alert. In operation, portions of the signal corresponding to the sensor being below the substrate can be compared analyzed to determine whether the criteria are met, or can be subject to a Fourier transform and compared to the reference spectrum.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

A computer program (also known as a program, software, software application, or code) can be written in any form of programming language, including compiled or interpreted languages, and it can be deployed in any form, including as a standalone program or as a module, component, subroutine, or other unit suitable for use in a computing environment. A computer program does not necessarily correspond to a file. A program can be stored in a portion of a file that holds other programs or data, in a single file dedicated to the program in question, or in multiple coordinated files (e.g., files that store one or more modules, sub programs, or portions of code). A computer program can be deployed to be executed on one computer or on multiple computers at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

While this specification contains many details, these should not be construed as limitations on the scope of what may be claimed, but rather as descriptions of features specific to particular examples. Certain features that are described in this specification in the context of separate implementations can also be combined. Conversely, various features that are described in the context of a single implementation can also be implemented in multiple embodiments separately or in any suitable subcombination.

A number of implementations have been described. Nevertheless, it will be understood that various modifications may be made without departing from the spirit and scope of the invention. Accordingly, other implementations are within the scope of the following claims.

What is claimed is:

1. A chemical mechanical polishing apparatus, comprising:
a platen supporting a polishing pad;
a carrier head to hold a surface of a substrate against the polishing pad, the carrier head including a retaining ring for holding the substrate;
an acoustic sensor supported on the platen;
a motor to generate relative motion between the platen and the carrier head so as to polish the substrate and such that the acoustic sensor travels in a path below the carrier head and the retaining ring; and
a controller configured to analyze a signal from the acoustic sensor and determine a characteristic of the retaining ring based on the signal.

2. The apparatus of claim 1, wherein the controller is configured to detect that the retaining ring is broken in based on the signal.

3. The apparatus of claim 2, wherein the controller is configured to generate an alert in response to detecting that the retaining ring is broken in.

4. The apparatus of claim 1, wherein the controller is configured to detect that grooving has formed on an inner surface of the retaining ring based on the signal.

5. The apparatus of claim 4, wherein the controller is configured to generate an alert in response to detecting that grooving has formed on the inner surface of the retaining ring.

6. The apparatus of claim 1, wherein the controller is configured to generate a measured spectrum of the signal.

7. The apparatus of claim 6, wherein the controller is configured to compare the measured spectrum to a reference spectrum.

8. The apparatus of claim 6, wherein the controller is configured to detect a signal strength in a band in the measured spectrum and compare the signal strength to a threshold.

9. The apparatus of claim 1, wherein the controller is configured to select portions of the signal corresponding to the acoustic sensor being positioned below the retaining ring.

10. A chemical mechanical polishing apparatus, comprising:
a platen supporting a polishing pad;
a carrier head to hold a surface of a substrate against the polishing pad, the carrier head including a retaining ring for holding the substrate;
an acoustic sensor supported on the platen;
a motor to generate relative motion between the platen and the carrier head so as to polish the substrate and such that the acoustic sensor travels in a path below the carrier head and the retaining ring; and
a controller configured to select portions of a signal from the acoustic sensor corresponding to the acoustic sensor being below the retaining ring and to generate an alert or to modify a polishing parameter based on the selected portions of the signal from the acoustic sensor.

11. The apparatus of claim 10, wherein the controller is configured to detect that the retaining ring is broken in based on the selected portions signal.

12. The apparatus of claim 10, wherein the controller is configured to detect that grooving has formed on an inner surface of the retaining ring based on the selected portions of the signal.

13. The apparatus of claim 10, wherein the controller is configured to modify the polishing parameter based on the selected portions of the signal.

14. A method of a chemical mechanical polishing apparatus, comprising:
bringing a surface of a substrate into contact with a polishing pad;
generating relative motion between the substrate and the polishing pad so as to polishing the substrate and using a carrier head to hold the substrate against lateral motion;
during polishing sweeping an acoustic sensor in a path below the carrier head and the retaining ring; and
analyzing a signal from the acoustic sensor and determining a characteristic of the retaining ring based on the signal.

15. The method of claim 14, comprising detecting that the retaining ring is broken in based on the signal.

16. The method of claim 15, comprising generating an alert in response to detecting that the retaining ring is broken in.

17. The method of claim 14, comprising detecting that grooving has formed on an inner surface of the retaining ring based on the signal.

18. The method of claim 17, comprising generating an alert in response to detecting that grooving has formed on the inner surface of the retaining ring.

19. The method of claim 14, comprising modifying a polishing parameter based on the signal.

20. The method of claim 14, comprising selecting a portion of the signal corresponding to the acoustic sensor being positioned below the retaining ring.
